(19) United States
(12) Patent Application Publication
(10) Pub. No.: US 2026/0305132 A1
(43) Pub. Date: Oct. 1, 2026

(54) DISPLAY DEVICE INCLUDING ENCAPSULATING LAYER

(71) Applicant: LG Display Co., Ltd., Seoul (KR)

(72) Inventors: Jae-Sung KIM, Paju-si (KR); Dong-Woo LEE, Paju-si (KR); Su-Min SON, Paju-si (KR)

(73) Assignee: LG Display Co., Ltd., Seoul (KR)

(21) Appl. No.: 19/330,506

(22) Filed: Sep. 16, 2025

(30) Foreign Application Priority Data
Mar. 27, 2025 (KR) 10-2025-0039658

(51) Int. Cl. H10K 59/80

(52) U.S. Cl. CPC H10K 59/873; H10K 59/8792

(57) ABSTRACT

A display device includes a substrate having a plurality of subpixels, each subpixel including a transistor disposed on the substrate and a light emitting diode connected to the transistor. A plurality of encapsulating layers are sequentially disposed on the light emitting diode, the encapsulating layers having gradually decreasing refractive indexes from a top portion to a bottom portion. A black matrix is disposed in a border region of the subpixels on the encapsulating layers, and a color filter layer is disposed in the subpixels on the encapsulating layers and the black matrix. By arranging the encapsulating layers with controlled refractive indexes, reflection of external light is minimized, thereby improving reflection visibility and display quality. The configuration enhances optical performance while providing protection against moisture and oxygen, enabling improved durability and image clarity in a compact structure.

### CROSS-REFERENCE TO RELATED APPLICATION

The present application claims the priority of Republic of Korea Patent Application No. 10-2025-0039658 filed on Mar. 27, 2025, which is hereby incorporated by reference in its entirety.

### BACKGROUND

### Technical Field

The present disclosure relates to a display device, and more particularly, to a display device including an encapsulating layer.

### Description of the Related Art

Recently, various flat panel display devices such as a liquid crystal display device (LCD), an organic light emitting diode (OLED) display device and a field emission display (FED) device having excellent properties of a thin profile, a light weight and a low power consumption have been developed and applied to various fields.

A display device includes a plurality of reflecting layers such as a metal layer. However, since an incident external light reflects on the plurality of reflecting layers, a reflection visibility is deteriorated and a display quality of an image displayed by the display device is deteriorated.

### BRIEF SUMMARY

The disclosure describes a display device that improves visibility and image quality through the use of multiple encapsulating layers with gradually decreasing refractive indexes positioned between the light emitting diode and the color filter layer. This graded index arrangement reduces external light reflection, disperses incident light at different angles, and thereby minimizes glare while enhancing display clarity. The encapsulating layers may include inorganic materials, which provide strong resistance to moisture and oxygen, as well as organic materials, which add flexibility and enable the device to be adapted for thin and flexible displays.

In addition to optical effects, the structure integrates functional layers directly on the encapsulation. A color filter on encapsulation configuration places the color filter layer above the encapsulating stack, which simplifies the process and reduces overall panel thickness while maintaining high optical performance. A touch on encapsulation configuration positions a mesh patterned touch electrode above the encapsulation and conceals it with a black matrix. This arrangement enhances aperture ratio, touch sensitivity, and visual performance without enlarging the bezel area.

Together, these structural features provide a comprehensive solution that addresses several challenges of modern display technology. The described arrangement minimizes ambient light reflection, improves durability and flexibility through the use of combined organic and inorganic materials, and enables integration of touch sensing and color filtering into the encapsulation stack. The result is a thinner and more efficient display device with improved readability, image quality, and manufacturing efficiency.

More specifically, the present disclosure is to provide a display device where a reflected light from a plurality of reflecting layers is minimized, a reflection visibility is improved and a fabrication process is optimized by disposing a plurality of encapsulating layers having gradually decreasing refractive indexes between a light emitting diode and a color filter layer.

In addition, the present disclosure is to provide a display device where a reflected light is minimized, a reflection visibility is improved and a display quality of an image is improved by forming a plurality of encapsulating layers of a plurality of organic layers and a plurality of inorganic layers having gradually decreasing refractive indexes between a light emitting diode and a color filter layer.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages, as embodied and broadly described herein, a display device includes: a substrate having a plurality of subpixels; a transistor in each of the plurality of subpixels on the substrate; a light emitting diode on the transistor and connected to the transistor; a plurality of encapsulating layers sequentially on the light emitting diode; and a color filter layer in the plurality of subpixels on the plurality of encapsulating layers, wherein the plurality of encapsulating layers have gradually decreasing refractive indexes in a direction from a side adjacent to the color filter layer toward a side adjacent to the light emitting diode.

In another aspect, a display device includes: a substrate having a plurality of subpixels; a transistor in each of the plurality of subpixels on the substrate; a light emitting diode on the transistor and connected to the transistor; first, second and third encapsulating layers sequentially on the light emitting diode; and a color filter layer in the plurality of subpixels on the third encapsulating layer, wherein each of the first, second, and third encapsulating layers include a plurality of insulating layers having gradually decreasing refractive indexes in a direction from a side adjacent the color filter layer toward a side adjacent the light emitting diode.

It is to be understood that both the foregoing general description and the following detailed description are explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this specification, illustrate embodiments of the disclosure and together with the description serve to explain the principles of the disclosure.

In the drawings:

FIG. 1 is a view showing a display device according to a first embodiment of the present disclosure;

FIG. 2 is a view showing a subpixel of a display device according to a first embodiment of the present disclosure;

FIG. 3 is a circuit diagram showing a subpixel of a display device according to a first embodiment of the present disclosure;

FIG. 4 is a cross-sectional view showing a subpixel of a display panel of a display device according to a first embodiment of the present disclosure;

FIG. 5 is a magnified view showing a light emitting diode and a plurality of encapsulating layers of FIG. 4;

FIG. 6 is a cross-sectional view showing a subpixel of a display panel of a display device according to a second embodiment of the present disclosure;

FIG. 7 is a magnified view showing a light emitting diode and a plurality of encapsulating layers of FIG. 6; and

FIG. 8 is a cross-sectional view showing a subpixel of a display panel of a display device according to a third embodiment of the present disclosure.

### DETAILED DESCRIPTION

Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure may be sufficiently thorough and complete to assist those skilled in the art to fully understand the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “display device” may include a display device in a narrow sense such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module or the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module or the QD module as well as a display device in a narrow sense such as the LCM, the OLED module or the QD module.

According to circumstances, the LCM, the OLED module or the QD module having a display panel and a driving unit may be expressed as “a display device,” and an electronic apparatus of a complete product including the LCM, the OLED module or the QD module may be expressed as “a set device.” For example, a display device in a narrow sense may include a display panel of a liquid crystal, an organic light emitting diode or a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or oxygen into the emitting element layer. In addition, the emitting element layer on the array may include an inorganic light emitting layer, for example, a nano-sized material layer or a quantum dot.

The thin film transistor of the present disclosure may include one of an oxide thin film transistor, an amorphous silicon thin film transistor, and a low temperature polycrystalline silicon thin film transistor.

Features of various embodiments of the present disclosure may be partially or entirely coupled to or combined with each other. They may be linked and operated technically in various ways as those skilled in the art may sufficiently understand. The aspects may be carried out independently of or in association with each other in various combinations.

Hereinafter, a display device according to various example embodiments of the present disclosure where an area of a non-display area is reduced and a narrow bezel is obtained by forming a plurality of power supply lines having the same layer and the same material as a bridge pattern for sensing a touch to overlap an auxiliary circuit unit will be described in detail with reference to the accompanying drawings.

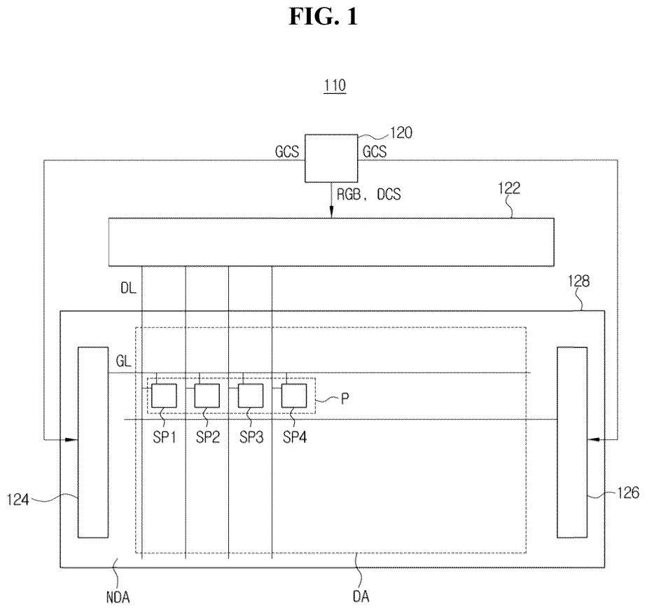

FIG. 1 is a view showing a display device according to a first embodiment of the present disclosure. Although the display device may be an organic light emitting diode (OLED) display device, it is not limited thereto. For example, the display device may be a quantum dot display device, a micro light emitting diode (LED) display device or a mini light emitting diode (LED) display device.

In FIG. 1, a display device 110 according to a first embodiment of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB, a data control signal DCS and a gate control signal GCS using an image signal and a plurality of timing signals including a data enable signal, a horizontal synchronization signal, a vertical synchronization signal and a clock signal transmitted from an external system such as a graphic card or a television system.

The timing controlling unit 120 transmits the image data RGB and the data control signal DCS to the data driving unit 122, and transmits the gate control signal GCS to the first and second gate driving units 124 and 126.

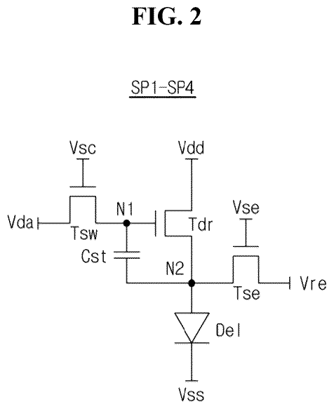

The data driving unit 122 generates a data signal (a data voltage) Vda (of FIG. 2) using the image data RGB and the data control signal DCS transmitted from the timing controlling unit 120 and transmits the data signal Vda to a data line DL of the display panel 128.

The first and second gate driving units 124 and 126 generate a gate signal (a gate voltage) Vsc and Vse (of FIG. 2) using the gate control signal GCS transmitted from the timing controlling unit 120 and applies the gate signal Vsc and Vse to a gate line GL of the display panel 128.

The first and second gate driving units 124 and 126 may have a gate in panel (GIP) type to be formed in a non-display area NDA of a substrate of the display panel 128 having the gate line GL, the data line DL and a pixel P.

Although the first and second gate driving units 124 and 126 are disposed in both side portions of the display panel 128 in the first embodiment of FIG. 1, one gate driving unit may be disposed in one side portion of the display panel 128 in another embodiment.

The display panel 128 includes a display area DA at a central portion thereof and a non-display area NDA surrounding the display area DA. The display panel 128 displays an image using the gate signal Vsc and Vse and the data signal Vda. Hereinafter, the gate signal Vsc and Vse may be referred to as the scan signal Vsc and sensing signal Vse.

For displaying an image, the display panel 128 includes a plurality of pixels P, a plurality of gate lines GL and a plurality of data lines DL in the display area DA.

Each of the plurality of pixels P includes first, second, third and fourth subpixels SP1, SP2, SP3 and SP4, and the gate line GL and the data line DL cross each other to define the first, second, third and fourth subpixels SP1, SP2, SP3 and SP4. Each of the first, second, third and fourth subpixels SP1, SP2, SP3 and SP4 is connected to the gate line GL and the data line DL. For example, the first, second, third and fourth subpixels SP1, SP2, SP3 and SP4 may correspond to red, green, blue and white colors, respectively.

In another embodiment, each of the plurality of pixels P includes first, second and third subpixels SP1, SP2 and SP3 corresponding to red, green and blue colors, respectively.

Each of the first, second, third and fourth subpixels SP1, SP2, SP3 and SP4 may include a plurality of transistors such as a switching transistor Tsw (of FIG. 2), a driving transistor Tdr (of FIG. 2) and a sensing transistor Tse (of FIG. 2), a storage capacitor Cst (of FIG. 2) and a light emitting diode Del (of FIG. 2).

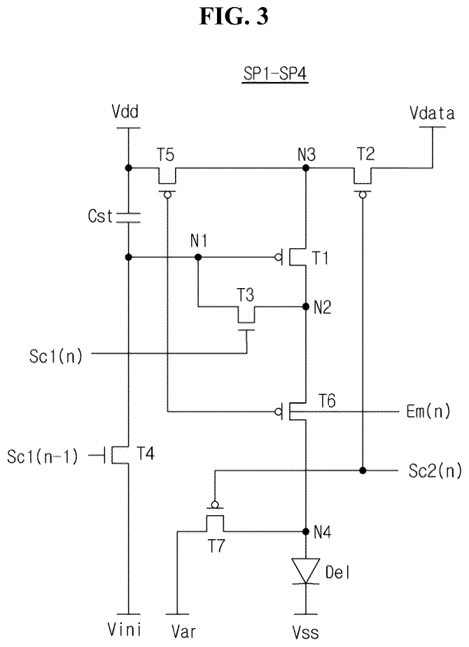

FIG. 2 is a view showing a subpixel of a display device according to a first embodiment of the present disclosure, and FIG. 3 is a circuit diagram showing a subpixel of a display device according to a first embodiment of the present disclosure.

In FIG. 2, each of the first, second, third and fourth subpixels SP1, SP2, SP3 and SP4 of the display panel 128 of the display device 110 according to a first embodiment of the present disclosure includes a switching transistor Tsw, a driving transistor Tdr, a sensing transistor Tse, a storage capacitor Cst and a light emitting diode Del.

Although each of the first, second, third and fourth subpixels SP1, SP2, SP3 and SP4 has a 3T1C structure having three transistors and one storage capacitor in the first embodiment of FIG. 2, each of the first, second, third and fourth subpixels SP1, SP2, SP3 and SP4 may have one of a 6T1C structure having six transistors and one storage capacitor, a 7T1C structure having seven transistors and one storage capacitor and a 8T1C structure having eight transistors and one storage capacitor in another embodiment.

Although the switching transistor Tsw, the driving transistor Tdr and the sensing transistor Tse may have a negative type (N type) in the first embodiment of FIG. 2, at least one of the switching transistor Tsw, the driving transistor Tdr and the sensing transistor Tse may have a positive type (P type) in another embodiment.

The switching transistor Tsw is switched according to a scan signal Vsc to transmit a data signal Vda to a first node N1.

A gate electrode of the switching transistor Tsw is connected to the gate line GL to receive the scan signal Vsc, a drain electrode of the switching transistor Tsw is connected to the data line DL to receive the data signal Vda, and a source electrode of the switching transistor Tsw is connected to the first node N1.

The driving transistor Tdr is switched according to a voltage of the first node N1 to transmit a high level signal (high level voltage) Vdd to a second node N2.

A gate electrode of the driving transistor Tdr is connected to the first node N1, a drain electrode of the driving transistor Tdr is connected to a high level power line to receive the high level signal Vdd, and a source electrode of the driving transistor Tdr is connected to the second node N2.

The sensing transistor Tse is switched according to a sensing signal (sensing voltage) Vse to transmit a reference signal (reference voltage) Vre to the second node N2 or transmit a voltage of the second node N2 to a reference line.

A gate electrode of the sensing transistor Tse is connected to the gate line GL to receive the sensing signal Vse, a drain electrode of the sensing transistor Tse is connected to the reference line to receive the reference signal Vre or transmit a voltage of the second node N2 to the reference line, and a source electrode of the sensing transistor Tse is connected to the second node N2.

The storage capacitor Cst keeps the data signal Vda supplied to the first node N1 for one frame and stores a threshold voltage Vth of the driving transistor Tdr.

A first capacitor electrode of the storage capacitor Cst is connected to the first node N1, and a second capacitor electrode of the storage capacitor Cst is connected to the second node N2.

The light emitting diode Del emits a light of a luminance proportional to a current of the driving transistor Tdr.

An anode of the light emitting diode Del is connected to the second node N2, and a cathode of the light emitting diode Del is connected to a low level power line to receive a low level signal (low level voltage) Vss.

The source electrode of the switching transistor Tsw, the gate electrode of the driving transistor Tdr and the first capacitor electrode of the storage capacitor Cst constitute the first node N1, and the source electrode of the driving transistor Tdr, the source electrode of the sensing transistor Tse, the second capacitor electrode of the storage capacitor Cst and the anode of the light emitting diode Del constitute the second node N2.

The light emitting diode Del may display an image having a luminance corresponding to the image data RGB according to a driving of subpixel circuits of the first, second, third and fourth subpixels SP1, SP2, SP3 and SP4.

In FIG. 3, each of first, second, third and fourth subpixels SP1, SP2, SP3 and SP4 (SP) of the display panel 128 of the display device 110 according to a first embodiment of the present disclosure includes first to seventh transistors T1 to T7, a storage capacitor Cst and a light emitting diode Del.

At least one of the first to seventh transistors T1 to T7 may be an oxide semiconductor thin film transistor, and the others of the first to seventh transistors T1 to T7 may be a low temperature polycrystalline silicon thin film transistor.

For example, the first, second, fifth, sixth and seventh transistors T1, T2, T5, T6 and T7 may be a positive (P) type low temperature polycrystalline silicon thin film transistor, and the third and fourth transistors T3 and T4 may be a negative (N) type oxide semiconductor thin film transistor.

Alternatively, the second, fifth, sixth and seventh transistors T2, T5, T6 and T7 may be a low temperature polycrystalline silicon thin film transistor, and the first, third and fourth transistors T1, T3 and T4 may be an oxide semiconductor thin film transistor.

The first transistor T1 as a driving transistor is switched according to a voltage of a first capacitor electrode of the storage capacitor Cst. A gate electrode of the first transistor T1 is connected to a first node N1, a source electrode of the first transistor T1 is connected to a third node N3, and a drain electrode of the first transistor T1 is connected to a second node N2.

The second transistor T2 as a switching transistor is switched according to an nth scan2 signal Sc2(n). A gate electrode of the second transistor T2 is connected to the nth scan2 signal Sc2(n), a source electrode of the second transistor T2 is connected to the third node N3, and a drain electrode of the second transistor T2 is connected to the data signal Vda.

The third transistor T3 as a sensing transistor is switched according to an nth scan1 signal Sc1(n). A gate electrode of the third transistor T3 is connected to the nth scan1 signal Sc1(n), a source electrode of the third transistor T3 is connected to the second node N2, and a drain electrode of the third transistor T3 is connected to the first node N1.

The fourth transistor T4 is switched according to an (n−1)th scan1 signal Sc1(n−1). A gate electrode of the fourth transistor T4 is connected to the (n−1)th scan1 signal Sc1(n−1), a source electrode of the fourth transistor T4 is connected to an initial signal (initialization voltage) Vini, and a drain electrode of the fourth transistor T4 is connected to the first node N1.

The fifth transistor T5 as an emission transistor is switched according to an nth emission signal Em(n). A gate electrode of the fifth transistor T5 is connected to the nth emission signal Em(n), a source electrode of the fifth transistor T5 is connected to a high level signal (high level voltage, e.g., high potential voltage) Vdd, and a drain electrode of the fifth transistor T5 is connected to the third node N3.

The sixth transistor T6 as an emission transistor is switched according to the nth emission signal Em(n). A gate electrode of the sixth transistor T6 is connected to the nth emission signal Em(n), a source electrode of the sixth transistor T6 is connected to the second node N2, and a drain electrode of the sixth transistor T6 is connected to a fourth node N4.

The seventh transistor T7 is switched according to the nth scan2 signal Sc2(n). A gate electrode of the seventh transistor T7 is connected to the nth scan2 signal Sc2(n), a source electrode of the seventh transistor T7 is connected to the fourth node N4, and a drain electrode of the seventh transistor T7 is connected to an anode reset voltage Var.

The storage capacitor Cst stores the data signal Vda and the threshold voltage Vth. A first capacitor electrode of the storage capacitor Cst is connected to the first node N1, and a second capacitor electrode of the storage capacitor Cst is connected to the high level signal Vdd.

The light emitting diode Del is connected between the sixth and seventh transistors T6 and T7 and the low level signal (low level voltage, e.g., low potential voltage) Vss to emit a light of a luminance proportional to a current of the first transistor T1. An anode of the light emitting diode Del is connected to the fourth node N4, and a cathode of the light emitting diode Del is connected to a low level signal Vss.

The gate electrode of the first transistor T1, the drain electrode of the third transistor T3, the drain electrode of the fourth transistor T4 and the first capacitor electrode of the storage capacitor Cst constitute the first node N1, and the drain electrode of the first transistor T1, the source electrode of the third transistor T3 and the source electrode of the sixth transistor T6 constitute the second node N2. The source electrode of the first transistor T1, the source electrode of the second transistor T2 and the drain electrode of the fifth transistor T5 constitute the third node N3, and the drain electrode of the sixth transistor T6, the source electrode of the seventh transistor T7 and the anode of the light emitting diode Del constitute the fourth node N4.

A cross-sectional structure of each subpixel SP1 to SP4 of the display panel 128 of the display device 110 will be illustrated with reference to a drawing.

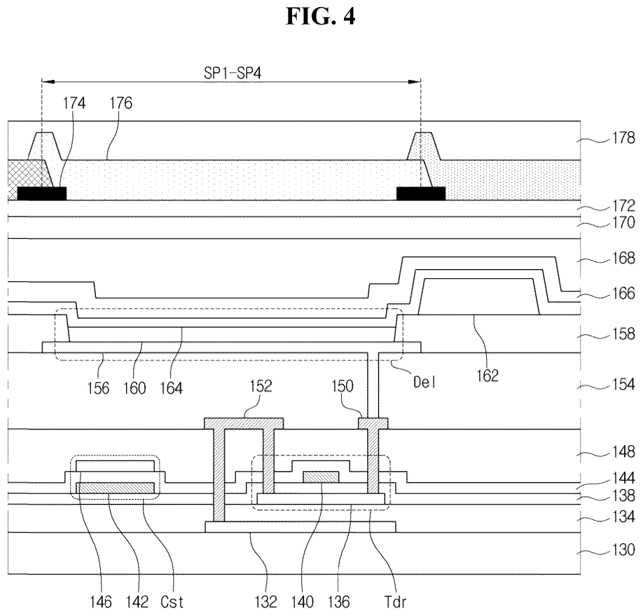

FIG. 4 is a cross-sectional view showing a subpixel of a display panel of a display device according to a first embodiment of the present disclosure.

In FIG. 4, a light shielding pattern 132 is disposed in each of the first, second, third and fourth subpixels SP1, SP2, SP3 and SP4 on a substrate 130, and a buffer layer 134 is disposed on the light shielding pattern 132 over the entire substrate 130.

The light shielding pattern 132 may block a light incident from a lower portion of the substrate 130.

For example, the light shielding pattern 132 may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

The buffer layer 134 may block a moisture or an oxygen permeating from an exterior.

For example, the buffer layer 134 may have a single layer or a multiple layer of an inorganic insulating material such as silicon oxide (SiO₂) and silicon nitride (SiNx).

A semiconductor layer 136 is disposed on the buffer layer 134 corresponding to the light shielding pattern 132, and a gate insulating layer 138 is disposed on the semiconductor layer 136 over the entire substrate 130.

The semiconductor layer 136 includes a channel region not doped with an impurity at a central portion thereof and source and drain regions doped with an impurity at both side portions of the channel region.

For example, the semiconductor layer 136 may include a polycrystalline semiconductor material such as polycrystalline silicon or an oxide semiconductor material such as indium gallium zinc oxide (IGZO), zinc oxide (ZnO), tin oxide (SnO₂), copper oxide (Cu₂O), nickel oxide (NiO), indium tin zinc oxide (ITZO) and indium aluminum zinc oxide (IAZO).

For example, the gate insulating layer 138 may have a single layer or a multiple layer of an inorganic insulating material such as silicon oxide (SiO₂) and silicon nitride (SiNx).

A gate electrode 140 is disposed on the gate insulating layer 138 corresponding to the channel region of the semiconductor layer 136, and a first capacitor electrode 142 separated from the gate electrode 140 is disposed on the gate insulating layer 138. A first interlayer insulating layer 144 is disposed on the gate electrode 140 and the first capacitor electrode 142 over the entire substrate 130.

The gate electrode 140 and the first capacitor electrode 142 may have the same layer and the same material as each other.

For example, the gate electrode 140 and the first capacitor electrode 142 may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

For example, the first interlayer insulating layer 144 may have a single layer or a multiple layer of an inorganic insulating material such as silicon oxide (SiO₂) and silicon nitride (SiNx).

A second capacitor electrode 146 is disposed on the first interlayer insulating layer 144 corresponding to the first capacitor electrode 142, and a second interlayer insulating layer 148 is disposed on the second capacitor electrode 146 over the entire substrate 130.

For example, the second capacitor electrode 146 may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

For example, the second interlayer insulating layer 148 may have a single layer or a multiple layer of an inorganic insulating material such as silicon oxide (SiO₂) and silicon nitride (SiNx).

The first capacitor electrode 142, the first interlayer insulating layer 144 and the second capacitor electrode 146 may constitute the storage capacitor Cst.

A source electrode 150 and a drain electrode 152 spaced apart from each other are disposed on the second interlayer insulating layer 148, and a planarizing layer 154 is disposed on the source electrode 150 and the drain electrode 152 over the entire substrate 130.

The source electrode 150 and the drain electrode 152 are connected to the source region and the drain region, respectively, of the semiconductor layer 136 through contact holes in the second interlayer insulating layer 148, the first interlayer insulating layer 144 and the gate insulating layer 138, and the drain electrode 152 is connected to the light shielding pattern 132 through a contact hole in the second interlayer insulating layer 148, the first interlayer insulating layer 144, the gate insulating layer 138 and the buffer layer 134.

The source electrode 150 and the drain electrode 152 may have the same layer and the same material as each other.

For example, the source electrode 150 and the drain electrode 152 may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

For example, the planarizing layer 154 may have a single layer or a multiple layer of an organic insulating material such as photoacryl and benzocyclobutene (BCB).

The semiconductor layer 136, the gate electrode 140, the source electrode 150 and the drain electrode 152 may constitute the driving transistor Tdr.

A first electrode 156 is disposed on the planarizing layer 154 corresponding to the source electrode 150, and a bank layer 158 is disposed on the first electrode 156.

The first electrode 156 is connected to the source electrode 150 through a contact hole in the planarizing layer 154.

For example, the first electrode 156 may be an anode and may have a single layer or a multiple layer of a transparent conductive material such as indium tin oxide (ITO) and indium zinc oxide (IZO) or an opaque metallic material such as aluminum (Al), silver (Ag), copper (Cu), lead (Pb), molybdenum (Mo), titanium (Ti) and an alloy thereof.

The bank layer 158 covers an edge portion of the first electrode 156 and has an opening exposing a central portion of the first electrode 156.

For example, the bank layer 158 may have a single layer or a multiple layer of an organic insulating material such as photoacryl and benzocyclobutene (BCB). To prevent a color mixture, the bank layer 158 may further include a light absorbing material such as a black carbon.

An emitting layer 160 is disposed on the first electrode 156 exposed through the opening of the bank layer 158, a spacer 162 is disposed on the bank layer 158, and a second electrode 164 is disposed on the emitting layer 160 and the spacer 162 over the entire substrate 130.

The emitting layer 160 contacts the first electrode 156 exposed through the opening of the bank layer 158 and a side surface of the opening of the bank layer 158.

The emitting layer 160 may include a hole assisting layer such as a hole injecting layer and a hole transporting layer, an emitting material layer and an electron assisting layer such as an electron transporting layer and an electron injecting layer.

For example, the spacer 162 may have a single layer or a multiple layer of an organic insulating material such as photoacryl and benzocyclobutene (BCB).

For example, the second electrode 164 may be a cathode and may have a single layer or a multiple layer of a transparent conductive material such as indium tin oxide (ITO) and indium zinc oxide (IZO) or a half-transmissive material or an opaque metallic material such as aluminum (Al), silver (Ag), copper (Cu), lead (Pb), magnesium (Mg), molybdenum (Mo), titanium (Ti) and an alloy thereof.

The first electrode 156, the emitting layer 160 and the second electrode 164 may constitute the light emitting diode Del.

A first encapsulating layer 166, a second encapsulating layer 168, a third encapsulating layer 170 and a fourth encapsulating layer 172 for preventing a permeation of a moisture are sequentially disposed on the second electrode 164 over the entire substrate 130. From the fourth encapsulating layer 172 to the first encapsulating layer 166, refractive indexes of the fourth, third, second and first encapsulating layers 172, 170, 168 and 166 may gradually decrease.

For example, the refractive index of the third encapsulating layer 170 may be smaller than the refractive index of the fourth encapsulating layer 172, the refractive index of the second encapsulating layer 168 may be smaller than the refractive index of the third encapsulating layer 170, and the refractive index of the first encapsulating layer 166 may be smaller than the refractive index of the second encapsulating layer 168.

For example, the refractive indexes of the first, second, third and fourth encapsulating layers 166, 168, 170 and 172 may be within a range of about 1.4 to about 1.6.

For example, each of the first, second, third and fourth encapsulating layers 166, 168, 170 and 172 may include an inorganic insulating material such as silicon oxide (SiO₂), silicon nitride (SiNx) and silicon oxynitride (SiONx) or an organic insulating material such as acryl resin, epoxy resin, phenolic resin, polyamide resin and polyimide resin.

When the first, second, third and fourth encapsulating layers 166, 168, 170 and 172 include an inorganic insulating material, the refractive indexes of the first, second, third and fourth encapsulating layers 166, 168, 170 and 172 may be determined by adjusting a ratio of a source gas such as silane (SiH₄), nitrous oxide (N₂O) and ammonia (NH₃), an applied power and a process pressure. When the first, second, third and fourth encapsulating layers 166, 168, 170 and 172 include an organic insulating material, the refractive indexes of the first, second, third and fourth encapsulating layers 166, 168, 170 and 172 may be determined by adjusting a resin composition ratio through addition of a compound.

A black matrix 174 is disposed on the fourth encapsulating layer 172 in a border region of the first, second, third and fourth subpixels SP1, SP2, SP3 and SP4, and a color filter layer 176 is disposed on the fourth encapsulating layer 172 and the black matrix 174 in the first, second, third and fourth subpixels SP1, SP2, SP3 and SP4.

The black matrix 174 may block a light from the light emitting diode Del of the adjacent subpixel to prevent a color mixture and may overlap the bank layer 158 and the spacer 162.

For example, the black matrix 174 may include a metallic material such as chromium (Cr) or an organic material such as a black resin including black carbon.

The color filter layer 176 selectively transmit a light emitted from the light emitting diode Del of each of the first, second, third and fourth subpixels SP1, SP2, SP3 and SP4 to assign a color. A refractive index of the color filter layer 176 may be greater than a refractive index of the fourth encapsulating layer 172.

For example, when the first, second, third and fourth subpixels SP1, SP2, SP3 and SP4 correspond to red, green, blue and white colors, respectively, and the light emitting diode Del emits a white colored light, the color filter layer 176 may include red, green and blue color filters in the first, second and third subpixels SP1, SP2 and SP3, respectively, and an additional color filter may not be disposed in the fourth subpixel SP4 to be omitted.

In another embodiment where each of the plurality of pixels P includes the first, second and third subpixels corresponding to red, green and blue colors, respectively, and the light emitting diode Del emits a white colored light, the color filter layer 176 may include red, green and blue color filters in the first, second and third subpixels, respectively.

End portions of the adjacent color filters may overlap each other over the black matrix 174.

From the color filter layer 176 to the first encapsulating layer 170, the refractive indexes of the color filter layer 176 and the fourth, third, second and first encapsulating layers 172, 170, 168 and 166 may gradually decrease.

A protecting layer 178 is disposed on the color filter layer 176 over the entire substrate 130.

For example, the protecting layer 178 may have a single layer or a multiple layer of an inorganic insulating material such as silicon oxide (SiO₂) and silicon nitride (SiNx) or an organic insulating material such as photoacryl and benzocyclobutene (BCB).

In the display device 110, reflection of the external light may be minimized due to the fourth, third, second and first encapsulating layers 172, 170, 168 and 166 having the gradually decreasing refractive indexes.

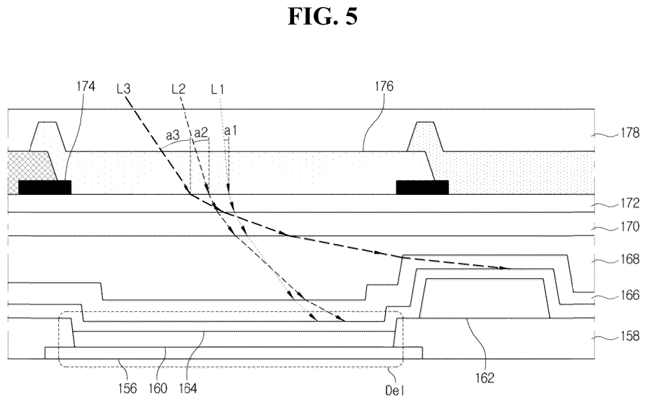

FIG. 5 is a magnified view showing a light emitting diode and a plurality of encapsulating layers of FIG. 4.

In FIG. 5, first, second and third external lights L1, L2 and L3 having different incident angles enter a front surface of the display device 110 according to a first embodiment of the present disclosure. The first, second and third external lights L1, L2 and L3 pass through the protecting layer 178, the color filter layer 176 and the fourth, third, second and first encapsulating layers 172, 170, 168 and 166 and reflect on the light emitting diode Del.

Since the color filter layer 176 and the fourth, third, second and first encapsulating layers 172, 170, 168 and 166 have different refractive indexes, the first, second and third external lights L1, L2 and L3 are refracted with different refractive angles at interfacial surface between two of the color filter layer 176 and the fourth, third, second and first encapsulating layers 172, 170, 168 and 166.

An incident angle and a refractive angle may be defined as an angel of an incident light and a refractive light, respectively, with respect to a normal line of a front surface of the substrate 130.

Since the refractive index of the fourth encapsulating layer 172 is smaller than the refractive index of the color filter layer 176, the first external light L1 having a relatively small first incident angle a1 is refracted with an eleventh refractive angle greater than the first incident angle a1 at the interfacial surface between the color filter layer 176 and the fourth encapsulating layer 172.

In addition, since the refractive index of the third encapsulating layer 170 is smaller than the refractive index of the fourth encapsulating layer 172, the first external light L1 having passed through the fourth encapsulating layer 172 with the eleventh refractive angle is refracted with a twelfth refractive angle greater than the eleventh refractive angle at the interfacial surface between the fourth encapsulating layer 172 and the third encapsulating layer 170.

Similarly, since the refractive index of the second encapsulating layer 168 is smaller than the refractive index of the third encapsulating layer 170, the first external light L1 having passed through the third encapsulating layer 170 with the twelfth refractive angle is refracted with a thirteenth refractive angle greater than the twelfth refractive angle at the interfacial surface between the third encapsulating layer 170 and the second encapsulating layer 168. Further, since the refractive index of the first encapsulating layer 166 is smaller than the refractive index of the second encapsulating layer 168, the first external light L1 having passed through the second encapsulating layer 168 with the thirteenth refractive angle is refracted with a fourteenth refractive angle greater than the thirteenth refractive angle at the interfacial surface between the second encapsulating layer 168 and the first encapsulating layer 166.

The order relation of the incident angle and the refractive angle according to the order relation of the refractive indexes is equally applied to each of the second and third external lights L2 and L3 having different incident angles.

As a result, the second external light L2 having a second incident angle a2 greater than the first incident angle a1 is refracted with a twenty-first refractive angle greater than the second incident angle a2 at the interfacial surface between the color filter layer 176 and the fourth encapsulating layer 172, and the second external light L2 having passed through the fourth encapsulating layer 172 with the twenty-first refractive angle is refracted with a twenty-second refractive angle greater than the twenty-first refractive angle at the interfacial surface between the fourth encapsulating layer 172 and the third encapsulating layer 170.

Further, the second external light L2 having passed through the third encapsulating layer 170 with the twenty-second refractive angle is refracted with a twenty-third refractive angle greater than the twenty-second refractive angle at the interfacial surface between the third encapsulating layer 170 and the second encapsulating layer 168, and the second external light L2 having passed through the second encapsulating layer 168 with the twenty-third refractive angle is refracted with a twenty-fourth refractive angle greater than the twenty-third refractive angle at the interfacial surface between the second encapsulating layer 168 and the first encapsulating layer 166.

The third external light L3 having a third incident angle a3 greater than the second incident angle a2 is refracted with a thirty-first refractive angle greater than the third incident angle a3 at the interfacial surface between the color filter layer 176 and the fourth encapsulating layer 172, and the third external light L3 having passed through the fourth encapsulating layer 172 with the thirty-first refractive angle is refracted with a thirty-second refractive angle greater than the thirty-first refractive angle at the interfacial surface between the fourth encapsulating layer 172 and the third encapsulating layer 170.

Further, the third external light L3 having passed through the third encapsulating layer 170 with the thirty-second refractive angle is refracted with a thirty-third refractive angle greater than the thirty-second refractive angle at the interfacial surface between the third encapsulating layer 170 and the second encapsulating layer 168, and the third external light L3 having passed through the second encapsulating layer 168 with the thirty-third refractive angle is refracted with a thirty-fourth refractive angle greater than the thirty-third refractive angle at the interfacial surface between the second encapsulating layer 168 and the first encapsulating layer 166.

Accordingly, since the first and second external lights L1 and L2 having a relatively small incident angle are refracted through the color filter layer 176 and the fourth, third, second and first encapsulating layers 172, 170, 168 and 166 with a relatively small refractive angle to reach a reflective layer such as the first electrode 156, the first and second external lights L1 and L2 may be reflected on the reflective layer. However, since the third external light L3 having a relatively great incident angle is refracted through the color filter layer 176 and the fourth, third, second and first encapsulating layers 172, 170, 168 and 166 with a relatively great refractive angle to reach a non-reflective layer such as the bank layer 158 or the spacer 162 instead of the light emitting diode Del, the third external light L3 may not be reflected on the non-reflective layer to dissipate.

Therefore, in the display device 110 according to a first embodiment of the present disclosure, since some of the external lights incident to the color filter layer 176 is not reflected and dissipates due to the fourth, third, second and first encapsulating layers 172, 170, 168 and 166 having the gradually decreasing refractive indexes, the reflected light of the external light is minimized, the reflection visibility is improved, and the display quality of the image is improved.

Although the plurality of encapsulating layers include four encapsulating layers 172, 170, 168 and 166 having the gradually decreasing refractive indexes in the first embodiment, the plurality of encapsulating layers may include two, three and five or more encapsulating layers having the gradually decreasing refractive indexes in another embodiment. When the plurality of encapsulating layers include organic layers and inorganic layers alternating with each other in another embodiment, the inorganic layer may be disposed as a top layer.

In another embodiment, each of the plurality of encapsulating layers may include an insulating layer having a gradually decreasing refractive indexes.

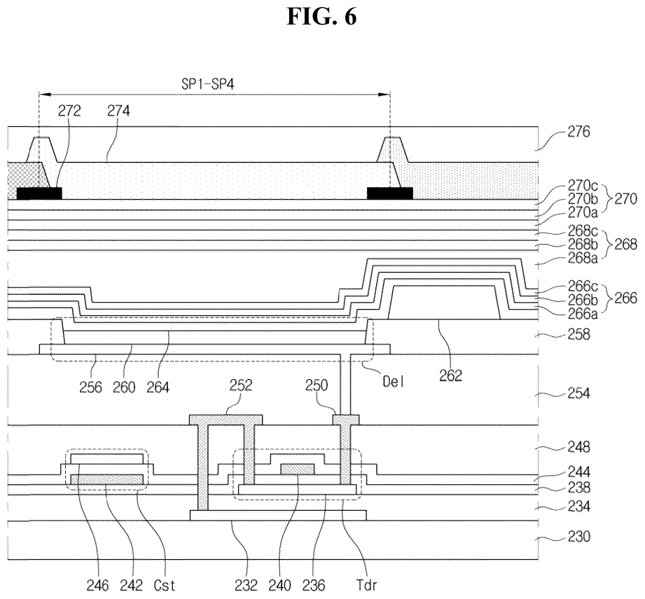

FIG. 6 is a cross-sectional view showing a subpixel of a display panel of a display device according to a second embodiment of the present disclosure. Illustration on a part the same as that of the first embodiment may be omitted.

In FIG. 6, a light shielding pattern 232, a buffer layer 234, a semiconductor layer 236, a gate insulating layer 238, a gate electrode 240, a first capacitor electrode 242, a first interlayer insulating layer 244, a second capacitor electrode 246, a second interlayer insulating layer 248, a source electrode 250, a drain electrode 252, a planarizing layer 254, a first electrode 256, a bank layer 258, an emitting layer 260, a spacer 262 and a second electrode 264 are disposed on a substrate 230. A structure of the light shielding pattern 232, the buffer layer 234, the semiconductor layer 236, the gate insulating layer 238, the gate electrode 240, the first capacitor electrode 242, the first interlayer insulating layer 244, the second capacitor electrode 246, the second interlayer insulating layer 248, the source electrode 250, the drain electrode 252, the planarizing layer 254, the first electrode 256, the bank layer 258, the emitting layer 260, the spacer 262 and the second electrode 264 is the same as that of the first embodiment of FIG. 4.

A first encapsulating layer 266, a second encapsulating layer 268 and a third encapsulating layer 270 for preventing a permeation of a moisture are sequentially disposed on the second electrode 264 over the entire substrate 230. The first encapsulating layer 266 includes eleventh, twelfth and thirteenth insulating layers 266a, 266b and 266c sequentially on the second electrode 264, the second encapsulating layer 268 includes twenty-first, twenty-second and twenty-third insulating layers 268a, 268b and 268c sequentially on the thirteenth insulating layer 266c, and the third encapsulating layer 270 includes thirty-first, thirty-second and thirty-third insulating layers 270a, 270b and 270c sequentially on the twenty-third insulating layer 268c.

From the thirteenth insulating layer 266c to the eleventh insulating layer 266a, refractive indexes of the thirteenth, twelfth and eleventh insulating layers 266c, 266b and 266a may gradually decrease. From the twenty-third insulating layer 268c to the twenty-first insulating layer 268a, refractive indexes of the twenty-third, twenty-second and twenty-first insulating layers 268c, 268b and 268a may gradually decrease. From the thirty-third insulating layer 270c to the thirty-first insulating layer 270a, refractive indexes of the thirty-third, thirty-second and thirty-first insulating layers 270c, 270b and 270a may gradually decrease.

For example, the refractive index of the twelfth insulating layer 266b may be smaller than the refractive index of the thirteenth insulating layer 266c, and the refractive index of the eleventh insulating layer 266a may be smaller than the refractive index of the twelfth insulating layer 266b. The refractive index of the twenty-second insulating layer 268b may be smaller than the refractive index of the twenty-third insulating layer 268c, and the refractive index of the twenty-first insulating layer 268a may be smaller than the refractive index of the twenty-second insulating layer 268b. The refractive index of the thirty-second insulating layer 270b may be smaller than the refractive index of the thirty-third insulating layer 270c, and the refractive index of the thirty-first insulating layer 270a may be smaller than the refractive index of the thirty-second insulating layer 270b.

Further, the refractive index of the thirteenth insulating layer 266c constituting an interfacial surface between the first and second encapsulating layers 266 and 268 may be greater than the refractive index of the twenty-first insulating layer 268a, and the refractive index of the twenty-third insulating layer 268c constituting an interfacial surface between the second and third insulating layers 268 and 270 may be greater than the refractive index of the thirty-first insulating layer 270a.

For example, the refractive indexes of the eleventh, twelfth, thirteenth, twenty-first, twenty-second, twenty-third, thirty-first, thirty-second and thirty-third insulating layers 266a, 266b, 266 c, 268 a, 268 b, 268 c, 270 a, 270 b and 270 c may be within a range of about 1.4 to about 1.6.

For example, each of the eleventh, twelfth and thirteenth insulating layers 266a, 266b and 266c of the first encapsulating layer 266 and the thirty-first, thirty-second and thirty-third insulating layers 270a, 270b and 270c of the third encapsulating layer 270 may include an inorganic insulating material such as silicon oxide (SiO₂), silicon nitride (SiNx) and silicon oxynitride (SiONx), and each of the twenty-first, twenty-second and twenty-third insulating layers 268a, 268b and 268c of the second encapsulating layer 268 may include an organic insulating material such as acryl resin, epoxy resin, phenolic resin, polyamide resin and polyimide resin.

The first and third encapsulating layers 266 and 270 of an inorganic insulating material may prevent a permeation of a moisture into the light emitting diode Del, and the second encapsulating layer 268 of an organic insulating material may assign a flexibility to the display device.

When the eleventh, twelfth and thirteenth insulating layers 266a, 266b and 266c of the first encapsulating layer 266 and the thirty-first, thirty-second and thirty-third 270a, 270b and 270c of the third encapsulating layer 270 include an inorganic insulating material, the refractive indexes of the eleventh, twelfth and thirteenth insulating layers 266a, 266b and 266c of the first encapsulating layer 266 and the thirty-first, thirty-second and thirty-third 270a, 270b and 270c of the third encapsulating layer 270 may be determined by adjusting a ratio of a source gas such as silane (SiH₄), nitrous oxide (N₂O) and ammonia (NH₃), an applied power and a process pressure.

When the twenty-first, twenty-second and twenty-third insulating layers 268a, 268b and 268c of the second encapsulating layer 268 include an organic insulating material, the refractive indexes of the twenty-first, twenty-second and twenty-third insulating layers 268a, 268b and 268c of the second encapsulating layer 268 may be determined by adjusting a resin composition ratio through addition of a compound.

A black matrix 272, a color filter layer 274 and a protecting layer 276 are disposed on the thirty-third insulating layer 270c of the third encapsulating layer 270. A structure of the black matrix 272, the color filter layer 274 and the protecting layer 276 is the same as that of the first embodiment of FIG. 4.

In the display device, reflection of the external light may be minimized due to the eleventh, twelfth and thirteenth insulating layers 266a, 266b and 266c of the first encapsulating layer 266, the twenty-first, twenty-second and twenty-third insulating layers 268a, 268b and 268c of the second encapsulating layer 268 and the thirty-first, thirty-second and thirty-third insulating layers 270a, 270b and 270c of the third encapsulating layer 270 having the gradually decreasing refractive indexes.

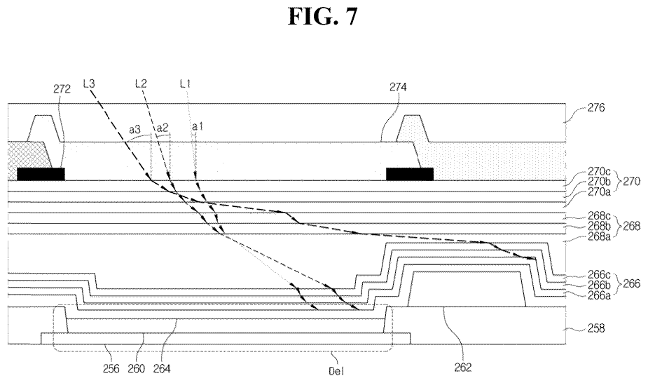

FIG. 7 is a magnified view showing a light emitting diode and a plurality of encapsulating layers of FIG. 6.

In FIG. 7, first, second and third external lights L1, L2 and L3 having different incident angles enter a front surface of the display device according to a second embodiment of the present disclosure. The first, second and third external lights L1, L2 and L3 pass through the protecting layer 276, the color filter layer 274, the thirty-first, thirty-second and thirty-third insulating layers 270a, 270b and 270c of the third encapsulating layer 270, the twenty-first, twenty-second and twenty-third insulating layers 268a, 268b and 268c of the second encapsulating layer 268 and the eleventh, twelfth and thirteenth insulating layers 266a, 266b and 266c of the first encapsulating layer 266 and reflect on the light emitting diode Del.

Since the color filter layer 274, the eleventh, twelfth and thirteenth insulating layers 266a, 266b and 266c, the twenty-first, twenty-second and twenty-third insulating layers 268a, 268b and 268c and the thirty-first, thirty-second and thirty-third 270a, 270b and 270c have different refractive indexes, the first, second and third external lights L1, L2 and L3 are refracted with different refractive angles at interfacial surface between two of the color filter layer 274, the thirty-first, thirty-second and thirty-third 270a, 270b and 270c, the twenty-first, twenty-second and twenty-third insulating layers 268a, 268b and 268c and the eleventh, twelfth and thirteenth insulating layers 266a, 266b and 266c.

An incident angle and a refractive angle may be defined as an angel of an incident light and a refractive light, respectively, with respect to a normal line of a front surface of the substrate 230.

Since the refractive index of the thirty-third insulating layer 270c is smaller than the refractive index of the color filter layer 274, the first external light L1 having a relatively small first incident angle a1 is refracted with an eleventh refractive angle greater than the first incident angle a1 at the interfacial surface between the color filter layer 274 and the thirty-third insulating layer 270c.

In addition, since the refractive index of the thirty-second insulating layer 270b is smaller than the refractive index of the thirty-third insulating layer 270c, the first external light L1 having passed through the thirty-third insulating layer 270c with the eleventh refractive angle is refracted with a twelfth refractive angle greater than the eleventh refractive angle at the interfacial surface between the thirty-third insulating layer 270c and the thirty-second insulating layer 270b. Since the refractive index of the thirty-first insulating layer 270a is smaller than the refractive index of the thirty-second insulating layer 270b, the first external light L1 having passed through the thirty-second insulating layer 270b with the twelfth refractive angle is refracted with a thirteenth refractive angle greater than the twelfth refractive angle at the interfacial surface between the thirty-second insulating layer 270b and the thirty-first insulating layer 270a.

Since the refractive index of the twenty-third insulating layer 268c is greater than the refractive index of the thirty-first insulating layer 270a, the first external light L1 having passed through the thirty-first insulating layer 270a with the thirteenth refractive angle is refracted with a fourteenth refractive angle smaller than the thirteenth refractive angle at the interfacial surface between the thirty-first insulating layer 270a and the twenty-third insulating layer 268c.

Since the first external light L1 of the first incident angle a1 passes through the twenty-third insulating layer 268c via three refractions of an increasing refractive angle and one refraction of a decreasing refractive angle, the fourteenth refractive angle may be greater than the first incident angle a1.

Further, since the refractive index of the twenty-second insulating layer 268b is smaller than the refractive index of the twenty-third insulating layer 268c, the first external light L1 having passed through the twenty-third insulating layer 268c with the fourteenth refractive angle is refracted with a fifteenth refractive angle greater than the fourteenth refractive angle at the interfacial surface between the twenty-third insulating layer 268c and the twenty-second insulating layer 268b. Since the refractive index of the twenty-first insulating layer 268a is smaller than the refractive index of the twenty-second insulating layer 268b, the first external light L1 having passed through the twenty-second insulating layer 268b with the fifteenth refractive angle is refracted with a sixteenth refractive angle greater than the fifteenth refractive angle at the interfacial surface between the twenty-second insulating layer 268b and the twenty-first insulating layer 268a.

Since the refractive index of the thirteenth insulating layer 266c is greater than the refractive index of the twenty-first insulating layer 268a, the first external light L1 having passed through the twenty-first insulating layer 268a with the sixteenth refractive angle is refracted with a seventeenth refractive angle smaller than the sixteenth refractive angle at the interfacial surface between the twenty-first insulating layer 268a and the thirteenth insulating layer 266c.

Since the first external light L1 of the first incident angle a1 passes through the thirteenth insulating layer 266c via five refractions of an increasing refractive angle and two refractions of a decreasing refractive angle, the seventeenth refractive angle may be greater than the first incident angle a1.

Further, since the refractive index of the twelfth insulating layer 266b is smaller than the refractive index of the thirteenth insulating layer 266c, the first external light L1 having passed through the thirteenth insulating layer 266c with the seventeenth refractive angle is refracted with an eighteenth refractive angle greater than the seventeenth refractive angle at the interfacial surface between the thirteenth insulating layer 266c and the twelfth insulating layer 266b. Since the refractive index of the eleventh insulating layer 266a is smaller than the refractive index of the twelfth insulating layer 266b, the first external light L1 having passed through the twelfth insulating layer 266b with the eighteenth refractive angle is refracted with a nineteenth refractive angle greater than the eighteenth refractive angle at the interfacial surface between the twelfth insulating layer 266b and the eleventh insulating layer 266a.

The order relation of the incident angle and the refractive angle according to the order relation of the refractive indexes is equally applied to each of the second and third external lights L2 and L3 having different incident angles.

As a result, the second external light L2 having a second incident angle a2 greater than the first incident angle a1 is refracted with a twenty-first refractive angle greater than the second incident angle a2 at the interfacial surface between the color filter layer 274 and the thirty-third insulating layer 270c.

The second external light L2 having passed through the thirty-third insulating layer 270c with the twenty-first refractive angle is refracted with a twenty-second refractive angle greater than the twenty-first refractive angle at the interfacial surface between the thirty-third insulating layer 270c and the thirty-second insulating layer 270b. The second external light L2 having passed through the thirty-second insulating layer 270b with the twenty-second refractive angle is refracted with a twenty-third refractive angle greater than the twenty-second refractive angle at the interfacial surface between the thirty-second insulating layer 270b and the thirty-first insulating layer 270a. The second external light L2 having passed through the thirty-first insulating layer 270a with the twenty-third refractive angle is refracted with a twenty-fourth refractive angle smaller than the twenty-third refractive angle at the interfacial surface between the thirty-first insulating layer 270a and the twenty-third insulating layer 268c. The twenty-fourth refractive angle may be greater than the second incident angle a2.

Further, the second external light L2 having passed through the twenty-third insulating layer 268c with the twenty-fourth refractive angle is refracted with a twenty-fifth refractive angle greater than the twenty-fourth refractive angle at the interfacial surface between the twenty-third insulating layer 268c and the twenty-second insulating layer 268b. The second external light L2 having passed through the twenty-second insulating layer 268b with the twenty-fifth refractive angle is refracted with a twenty-sixth refractive angle greater than the twenty-fifth refractive angle at the interfacial surface between the twenty-second insulating layer 268b and the twenty-first insulating layer 268a. The second external light L2 having passed through the twenty-first insulating layer 268a with the twenty-sixth refractive angle is refracted with a twenty-seventh refractive angle smaller than the twenty-sixth refractive angle at the interfacial surface between the twenty-first insulating layer 268a and the thirteenth insulating layer 266c. The twenty-seventh refractive angle may be greater than the second incident angle a2.

In addition, the second external light L2 having passed through the thirteenth insulating layer 266c with the twenty-seventh refractive angle is refracted with a twenty-eighth refractive angle greater than the twenty-seventh refractive angle at the interfacial surface between the thirteenth insulating layer 266c and the twelfth insulating layer 266b. The second external light L2 having passed through the twelfth insulating layer 266b with the twenty-eighth refractive angle is refracted with a twenty-ninth refractive angle greater than the twenty-eighth refractive angle at the interfacial surface between the twelfth insulating layer 266b and the eleventh insulating layer 266a.

Similarly, the third external light L3 having a third incident angle a3 greater than the second incident angle a2 is refracted with a thirty-first refractive angle greater than the third incident angle a3 at the interfacial surface between the color filter layer 274 and the thirty-third insulating layer 270c.

The third external light L3 having passed through the thirty-third insulating layer 270c with the thirty-first refractive angle is refracted with a thirty-second refractive angle greater than the thirty-first refractive angle at the interfacial surface between the thirty-third insulating layer 270c and the thirty-second insulating layer 270b. The third external light L3 having passed through the thirty-second insulating layer 270b with the thirty-second refractive angle is refracted with a thirty-third refractive angle greater than the thirty-second refractive angle at the interfacial surface between the thirty-second insulating layer 270b and the thirty-first insulating layer 270a. The third external light L3 having passed through the thirty-first insulating layer 270a with the thirty-third refractive angle is refracted with a thirty-fourth refractive angle smaller than the thirty-third refractive angle at the interfacial surface between the thirty-first insulating layer 270a and the twenty-third insulating layer 268c. The thirty-fourth refractive angle may be greater than the third incident angle a3.

Further, the third external light L3 having passed through the twenty-third insulating layer 268c with the thirty-fourth refractive angle is refracted with a thirty-fifth refractive angle greater than the thirty-fourth refractive angle at the interfacial surface between the twenty-third insulating layer 268c and the twenty-second insulating layer 268b. The third external light L3 having passed through the twenty-second insulating layer 268b with the thirty-fifth refractive angle is refracted with a thirty-sixth refractive angle greater than the thirty-fifth refractive angle at the interfacial surface between the twenty-second insulating layer 268b and the twenty-first insulating layer 268a. The third external light L3 having passed through the twenty-first insulating layer 268a with the thirty-sixth refractive angle is refracted with a thirty-seventh refractive angle smaller than the thirty-sixth refractive angle at the interfacial surface between the twenty-first insulating layer 268a and the thirteenth insulating layer 266c. The thirty-seventh refractive angle may be greater than the third incident angle a3.

In addition, the third external light L3 having passed through the thirteenth insulating layer 266c with the thirty-seventh refractive angle is refracted with a thirty-eighth refractive angle greater than the thirty-seventh refractive angle at the interfacial surface between the thirteenth insulating layer 266c and the twelfth insulating layer 266b. The third external light L3 having passed through the twelfth insulating layer 266b with the thirty-eighth refractive angle is refracted with a thirty-ninth refractive angle greater than the thirty-eighth refractive angle at the interfacial surface between the twelfth insulating layer 266b and the eleventh insulating layer 266a.

Accordingly, since the first and second external lights L1 and L2 having a relatively small incident angle are refracted through the color filter layer 274, the thirty-third, thirty-second and thirty-first insulating layers 270c, 270b and 270a, the twenty-third, twenty-second and twenty-first insulating layers 268c, 268b and 268a and the thirteenth, twelfth and eleventh insulating layers 266c, 266b and 266a with a relatively small refractive angle to reach a reflective layer such as the first electrode 256, the first and second external lights L1 and L2 may be reflected on the reflective layer. However, since the third external light L3 having a relatively great incident angle is refracted through the color filter layer 274, the thirty-third, thirty-second and thirty-first insulating layers 270c, 270b and 270a, the twenty-third, twenty-second and twenty-first insulating layers 268c, 268b and 268a and the thirteenth, twelfth and eleventh insulating layers 266c, 266b and 266a with a relatively great refractive angle to reach a non-reflective layer such as the bank layer 258 or the spacer 262 instead of the light emitting diode Del, the third external light L3 may not be reflected on the non-reflective layer to dissipate.

Therefore, in the display device according to a second embodiment of the present disclosure, since some of the external lights incident to the color filter layer 274 is not reflected and dissipates due to the thirty-third, thirty-second and thirty-first insulating layers 270c, 270b and 270a of the third encapsulating layer 270, the twenty-third, twenty-second and twenty-first insulating layers 268c, 268b and 268a of the second encapsulating layer 268 and the thirteenth, twelfth and eleventh insulating layers 266c, 266b and 266a of the first encapsulating layer 266 having the gradually decreasing refractive indexes, the reflected light of the external light is further minimized, the reflection visibility is further improved, and the display quality of the image is further improved.

Although each of the first, second and third encapsulating layers 266, 268 and 270 includes three insulating layers having the gradually decreasing refractive indexes in the second embodiment, each of the first, second and third encapsulating layers 266, 268 and 270 may include two, three and five or more insulating layers having the gradually decreasing refractive indexes in another embodiment.

In another embodiment, a touch electrode for sensing a touch may be disposed under the black matrix.

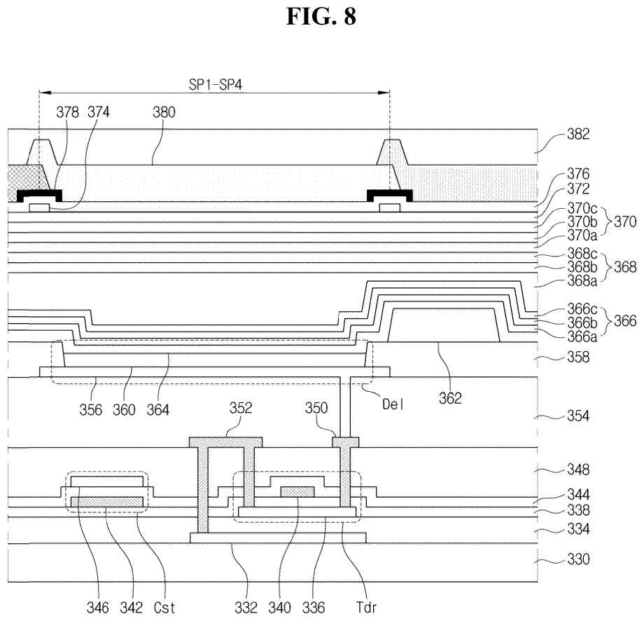

FIG. 8 is a cross-sectional view showing a subpixel of a display panel of a display device according to a third embodiment of the present disclosure. Illustration on a part the same as that of the second embodiment may be omitted.

In FIG. 8, a light shielding pattern 332, a buffer layer 334, a semiconductor layer 336, a gate insulating layer 338, a gate electrode 340, a first capacitor electrode 342, a first interlayer insulating layer 344, a second capacitor electrode 346, a second interlayer insulating layer 348, a source electrode 350, a drain electrode 352, a planarizing layer 354, a first electrode 356, a bank layer 358, an emitting layer 360, a spacer 362, a second electrode 364, a first encapsulating layer 366, a second encapsulating layer 368 and a third encapsulating layer 370 are disposed on a substrate 330. A structure of the light shielding pattern 332, the buffer layer 334, the semiconductor layer 336, the gate insulating layer 338, the gate electrode 340, the first capacitor electrode 342, the first interlayer insulating layer 344, the second capacitor electrode 346, the second interlayer insulating layer 348, the source electrode 350, the drain electrode 352, the planarizing layer 354, the first electrode 356, the bank layer 358, the emitting layer 360, the spacer 362, the second electrode 364, the first encapsulating layer 366, the second encapsulating layer 368 and the third encapsulating layer 370 is the same as that of the second embodiment of FIG. 6.

A first touch buffer layer 372 is disposed on the third encapsulating layer 370 over the entire substrate 330, and a touch electrode 374 is disposed in a border region of the first, second, third and fourth subpixels SP1, SP2, SP3 and SP4 on the first touch buffer layer 372.

The first touch buffer layer 372 may include an inorganic insulating material such as silicon oxide (SiO₂) and silicon nitride (SiNx) or an organic insulating material such as photoacryl and benzocyclobutene (BCB).

The touch electrode 374 may have a mesh shape (net shape) including a plurality of open portions, and each open portion may correspond to the emitting layer 360 to improve an aperture ratio and an emission efficiency of the display device.

A touch is sensed by detecting a change of a capacitance of the mesh shape of the touch electrode 374 due to the touch.

For example, the touch electrode 374 may include a metallic material such as molybdenum (Mo), aluminum (Al), chromium (Cr), gold (Au), titanium (Ti), nickel (Ni), neodymium (Nd), copper (Cu) and an alloy thereof or a transparent conductive material such as indium tin oxide (ITO) and indium zinc oxide (IZO).

A second touch buffer layer 376 is disposed on the touch electrode 374 over the entire substrate 330, and a black matrix 378 is disposed on the second touch buffer layer 376 in the border region of the first, second, third and fourth subpixels SP1, SP2, SP3 and SP4.

The black matrix 378 may block a light from the light emitting diode Del of the adjacent subpixel to prevent a color mixture. The black matrix 378 may completely cover and overlap the touch electrode 374.

For example, a width of the black matrix 378 may be greater than a width of the touch electrode 374, and the black matrix 378 may include a metallic material such as chromium (Cr) or an organic material such as a black resin including black carbon.

A color filter layer 380 and a protecting layer 382 are disposed on the black matrix 378. A structure of the color filter layer 380 and the protecting layer 382 is the same as that of the second embodiment of FIG. 6.

In the display device according to a third embodiment of the present disclosure, since some of the external lights incident to the color filter layer 380 is not reflected and dissipates due to the thirty-third, thirty-second and thirty-first insulating layers 370c, 370b and 370a of the third encapsulating layer 370, the twenty-third, twenty-second and twenty-first insulating layers 368c, 368b and 368a of the second encapsulating layer 368 and the thirteenth, twelfth and eleventh insulating layers 366c, 366b and 366a of the first encapsulating layer 366 having the gradually decreasing refractive indexes, the reflected light of the external light is further minimized, the reflection visibility is further improved, and the display quality of the image is further improved.

In addition, since the display device is formed to have a touch on encapsulation layer (TOE) structure where the touch electrode 374 is disposed on the first, second and third encapsulating layers 366, 368 and 370 and a color filter layer on encapsulation layer (COE) structure where the color filter layer 380 is disposed on the first, second and third encapsulating layers 366, 368 and 370, an image display performance and a touch performance are improved.

Consequently, in the display device according to the present disclosure, a reflected light from a plurality of reflecting layers is minimized, a reflection visibility is improved and a fabrication process is optimized by disposing a plurality of encapsulating layers having gradually decreasing refractive indexes between a light emitting diode and a color filter layer.

In addition, a reflected light is minimized, a reflection visibility is improved and a display quality of an image is improved by forming a plurality of encapsulating layers of a plurality of organic layers and a plurality of inorganic layers having gradually decreasing refractive indexes between a light emitting diode and a color filter layer.

In sum, the present disclosure describes a display device architecture that incorporates a plurality of encapsulating layers with gradually decreasing refractive indexes between the light emitting diode and the color filter. By tailoring refractive indexes across these layers, external light reflection is significantly reduced, thereby improving reflection visibility, contrast, and overall image quality. These layers are fabricated from combinations of organic and inorganic insulating materials, offering both optical tuning and robust protection against moisture and oxygen ingress.

One aspect of the present disclosure is the hybrid encapsulation stack that alternates inorganic and organic layers. The inorganic layers provide strong barrier properties, while the organic layers contribute flexibility, making the device suitable for thin and potentially flexible displays. The refractive index gradient further refracts incident light at multiple interfaces, redirecting high angle rays toward non reflective elements such as bank layers or spacers, where they dissipate instead of reflecting back. This controlled refraction mechanism minimizes glare and enhances display performance without requiring complex pixel circuit modifications.

In addition, the present disclosure integrates Touch on Encapsulation and Color on Encapsulation structures. By positioning the touch electrode and color filter layer directly on the encapsulation stack, the overall device thickness is reduced, fabrication is simplified, and both touch sensitivity and color rendering are improved. These features optimize the optical, mechanical, and functional properties of the display, addressing challenges in reflection suppression, durability, and integration efficiency.

It will be apparent to those skilled in the art that various modifications and variation may be made in the present disclosure without departing from the scope of the disclosure. Thus, it is intended that the present disclosure cover the modifications and variations of this disclosure provided they come within the scope of the appended claims and their equivalents.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate having a plurality of subpixels;
a transistor in each of the plurality of subpixels on the substrate;
a light emitting diode on the transistor and connected to the transistor;
a plurality of encapsulating layers sequentially on the light emitting diode; and
a color filter layer in the plurality of subpixels on the plurality of encapsulating layers,
wherein the plurality of encapsulating layers have gradually decreasing refractive indexes in a direction from a side adjacent to the color filter layer toward a side adjacent to the light emitting diode.

2. The display device of claim 1, further comprising a black matrix in a border region of the plurality of subpixels on the plurality of encapsulating layers,
wherein the color filter layer is on the black matrix.

3. The display device of claim 1, wherein the refractive indexes of the plurality of encapsulating layers are within a range of 1.4 to 1.6.

4. The display device of claim 1, wherein each of the plurality of encapsulating layers includes at least one material selected form the group consisting of silicon oxide, silicon nitride, silicon oxynitride, acryl resin, epoxy resin, phenolic resin, polyamide resin, and polyimide resin.

5. The display device of claim 1, wherein the plurality of encapsulating layers include organic layers and inorganic layers alternating with each other, and an inorganic layer is disposed as an uppermost one of the plurality of encapsulating layers.

6. The display device of claim 1, wherein the plurality of encapsulating layers include first, second, third, and fourth encapsulating layers sequentially on the light emitting diode,
wherein the refractive index of the fourth encapsulating layer is smaller than a refractive index of the color filter layer,
wherein the refractive index of the third encapsulating layer is smaller than the refractive index of the fourth encapsulating layer,
wherein the refractive index of the second encapsulating layer is smaller than the refractive index of the third encapsulating layer, and
wherein the refractive index of the first encapsulating layer is smaller than the refractive index of the second encapsulating layer.

7. The display device of claim 1, further comprising:
a light shielding pattern on the substrate;
a buffer layer on the light shielding pattern;
a semiconductor layer on the buffer layer corresponding to the light shielding pattern;
a gate insulating layer on the semiconductor layer;
a gate electrode on the gate insulating layer corresponding to the semiconductor layer;
a first capacitor electrode on the gate insulating layer and spaced apart from the gate electrode;
a first interlayer insulating layer on the gate electrode and the first capacitor electrode;
a second capacitor electrode on the first interlayer insulating layer corresponding to the first capacitor electrode;
a second interlayer insulating layer on the second capacitor electrode; and
a source electrode and a drain electrode on the second interlayer insulating layer and spaced apart from each other,
wherein the semiconductor layer, the gate electrode, the source electrode and the drain electrode constitute the transistor.

8. The display device of claim 7, further comprising:
a planarizing layer on the source electrode and the drain electrode;
a first electrode on the planarizing layer corresponding to the source electrode;
a bank layer covering an edge portion of the first electrode and exposing a central portion of the first electrode;
an emitting layer on the first electrode;
a spacer on the bank layer; and
a second electrode on the emitting layer and the spacer,
wherein the first electrode, the emitting layer and the second electrode constitute the light emitting diode.

9. The display device of claim 8, wherein the black matrix overlaps the bank layer and the spacer.

10. A display device, comprising:
a substrate having a plurality of subpixels;
a transistor in each of the plurality of subpixels on the substrate;
a light emitting diode on the transistor and connected to the transistor;
first, second and third encapsulating layers sequentially on the light emitting diode and
a color filter layer in the plurality of subpixels on the third encapsulating layer,
wherein each of the first, second, and third encapsulating layers include a plurality of insulating layers having gradually decreasing refractive indexes in a direction from a side adjacent to the color filter layer toward a side adjacent to the light emitting diode.

11. The display device of claim 10, further comprising a black matrix in a border region of the plurality of subpixels on the third encapsulating layer,
wherein the color filter layer is on the black matrix.

12. The display device of claim 10, wherein the refractive indexes of the plurality of encapsulating layers are within a range of 1.4 to 1.6.

13. The display device of claim 10, wherein each of the plurality of insulating layers of the first encapsulating layer and the plurality of insulating layers of the third encapsulating layer includes at least one material selected from the group consisting of silicon oxide, silicon nitride, and silicon oxynitride, and
wherein each of the plurality of insulating layers of the second encapsulating layer includes at least one material selected from the group consisting of acryl resin, epoxy resin, phenolic resin, polyamide resin and polyimide resin.

14. The display device of claim 10, wherein the first encapsulating layer includes eleventh, twelfth and thirteenth insulating layers sequentially on the light emitting diode,
wherein the second encapsulating layer includes twenty-first, twenty-second and twenty-third insulating layers sequentially on the thirteenth insulating layer,
wherein the third encapsulating layer includes thirty-first, thirty-second and thirty-third insulating layers sequentially on the twenty-third insulating layer,
wherein the refractive index of the thirty-third insulating layer is smaller than a refractive index of the color filter layer,
wherein the refractive index of the thirty-second insulating layer is smaller than the refractive index of the thirty-third insulating layer,
wherein the refractive index of the thirty-first insulating layer is smaller than the refractive index of the thirty-second insulating layer,
wherein the refractive index of the twenty-second insulating layer is smaller than the refractive index of the twenty-third insulating layer,
wherein the refractive index of the twenty-first insulating layer is smaller than the refractive index of the twenty-second insulating layer,
wherein the refractive index of the twelfth insulating layer is smaller than the refractive index of the thirteenth insulating layer, and
wherein the refractive index of the eleventh insulating layer is smaller than the refractive index of the twelfth insulating layer.

15. The display device of claim 14, wherein the refractive index of the twenty-third insulating layer is greater than the refractive index of the thirty-first insulating layer, and
wherein the refractive index of the thirteenth insulating layer is greater than the refractive index of the twenty-first insulating layer.

16. The display device of claim 11, further comprising:
a first electrode on the transistor;
a bank layer covering an edge portion of the first electrode and exposing a central portion of the first electrode;
an emitting layer on the first electrode;
a spacer on the bank layer; and
a second electrode on the emitting layer and the spacer,
wherein the first electrode, the emitting layer and the second electrode constitute the light emitting diode, and
wherein the black matrix overlaps the bank layer and the spacer.

17. The display device of claim 16, further comprising:
a first touch buffer layer on the third encapsulating layer;
a touch electrode in a border region of the plurality of subpixels on the first touch buffer layer; and
a second touch buffer layer between the touch electrode and the black matrix.

18. The display device of claim 17, wherein a width of the touch electrode is smaller than a width of the black matrix.

19. The display device of claim 17, wherein the touch electrode has a mesh shape including a plurality of open portions, and each open portion corresponds to the emitting layer.
